(19) United States
(12) Patent Application Publication
(10) Pub. No.: US 2026/0293031 A1
(43) Pub. Date: Sep. 24, 2026

(54) SERVER CHASSIS AND SERVER

(71) Applicant: WISTRON CORPORATION, New Taipei City (TW)

(72) Inventor: Jun Hao WANG, New Taipei City (TW)

(73) Assignee: WISTRON CORPORATION, New Taipei City (TW)

(21) Appl. No.: 19/313,508

(22) Filed: Aug. 28, 2025

(30) Foreign Application Priority Data
Mar. 24, 2025 (CN) 202510353688.X

(51) Int. Cl. H05K 7/14

(52) U.S. Cl. CPC H05K 7/1487

(57) ABSTRACT

A server chassis includes a cover body. The cover body may be assembled with a bottom shell of the chassis. The cover body includes a top plate, a slider, and a windshield member. The slider is slidably connected to the top plate. The windshield member is rotatably pivoted to the top plate. In response to that the slider is moved relative to the top plate, the windshield member is driven by the slider to rotate relative to the top plate. The cover body may be applied to the server chassis to provide a wind-shielding effect corresponding to vents of servers of different heights.

### CROSS-REFERENCE TO RELATED APPLICATIONS

This application claims the priority and benefit of Chinese Application No. 202510353688.X filed on Mar. 24, 2025, the disclosure of which is hereby incorporated in its entirety by reference herein.

### TECHNICAL FIELD

A server chassis and a server are provided. The server chassis is applicable to the server.

### BACKGROUND

### Related Art

In recent years, with rapid development of artificial intelligence technologies, demands for servers continue to increase. Servers provided by various manufacturers come in a variety of models and specifications to satisfy requirements of different application scenarios. However, for a customer who needs servers from different manufacturers to be supported at the same time, a challenge of how to make different servers compatible needs to be faced.

A conventional server mounting cage is usually designed for a specific model or manufacturer, and it is difficult to flexibly adapt such a conventional server mounting cage to a variety of servers. Particularly, different models of servers may have different heights. When the different models of servers are assembled to the server mounting cage, a large gap may be formed between a server and a server chassis. Such a gap affects heat dissipation efficiency.

### SUMMARY

In view of this, some embodiments of the present disclosure provide a server chassis and a server. A server having the server chassis may be applied to a server mounting cage, has high compatibility, and can effectively adapt to heat dissipation requirements of servers of different heights. Thereby, problems in the related art can be improved.

In some embodiments, a server chassis includes a cover body. The cover body includes a top plate, a slider, and a windshield member. The slider is slidably connected to the top plate or slidably disposed on the top plate. The windshield member is rotatably pivoted to the top plate. In response to that the slider is moved relative to the top plate, the windshield member is driven by the slider to rotate relative to the top plate.

In some embodiments, the server chassis further includes a bottom shell. The cover body is fixed or detachably fixed to the bottom shell to form a vent.

In some embodiments, the slider is slidably connected to the top plate or slidably disposed on the top plate to enable the slider to be at a first position or a second position, the windshield member is rotatably pivoted to the top plate to enable the windshield member to be at a first angular position or a second angular position, and in response to that the slider is moved from the first position toward the second position, the windshield member is driven by the slider to rotate from the first angular position toward the second angular position.

In some embodiments, the cover body further includes a linkage member. Two ends of the linkage member are respectively pivoted to the slider and the windshield member. In response to that the slider is moved from the first position toward the second position, the windshield member is caused by the slider to rotate from the first angular position toward the second angular position.

In some embodiments, the linkage member is a plate member. Two protruding arms provided on one of the two sides of the plate member are two first pivot arms, and two protruding arms provided on the other of the two sides of the plate member are two second pivot arms. The two first pivot arms are pivoted to the slider. The two second pivot arms are pivoted to the windshield member.

In some embodiments, a first sliding column is disposed on the top plate, the slider has a first sliding rail, and the first sliding column is slidably disposed on the first sliding rail to enable the slider to move to a first position or a second position along the first sliding rail by using the first sliding column.

In some embodiments, a first sliding column is disposed on the slider, the top plate has a first sliding rail, and the first sliding column is slidably disposed on the first sliding rail to enable the slider to move to a first position or a second position in response to that the first sliding column is moved along the first sliding rail.

In some embodiments, the cover body further includes a detent member and a positioning member, where the detent member has a plurality of positioning portions, the positioning member is fixed to the slider, and the positioning member is selectively located at one of the plurality of positioning portions.

In some embodiments, the detent member is slidably disposed on the top plate to enable the detent member to be at a first fixed position or a second fixed position. In response to that the detent member is moved from the first fixed position toward the second fixed position, the positioning member is moved from one of the plurality of positioning portions toward another of the plurality of positioning portions, to drive the slider to move from a first position toward a second position, thereby causing the windshield member to rotate from a first angular position toward a second angular position through the connection relationship between the slider and the windshield member.

In some embodiments, the top plate has a sliding groove, and the positioning member is slidably disposed in the sliding groove and is selectively located at one of the plurality of positioning portions.

In some embodiments, a movement path of the positioning member is parallel to the plurality of positioning portions or forms angles with the plurality of positioning portions.

In some embodiments, each of the positioning portions includes a positioning sub-portion and an abutting sub-portion. One end of the positioning sub-portion is connected to the abutting sub-portion. That the positioning member is located at one of the positioning portions is that the positioning member is located at the positioning sub-portion of one of the positioning portions.

In some embodiments, each of the positioning portions further includes a guide sub-portion. The guide sub-portion is connected to another end of the positioning sub-portion. The guide sub-portion is configured to guide the positioning member to leave the positioning sub-portion.

In some embodiments, the cover body further includes an elastic member. Two ends of the elastic member are respectively connected to the slider and the top plate. The elastic member applies or constantly applies a first acting force to pull the slider toward a first position.

In some embodiments, the top plate has a groove, and the detent member is accommodated in the groove.

In some embodiments, a surface of the detent member is provided with a pushing portion. A force is applied to the pushing portion to enable the positioning member to be selectively located at one of the plurality of positioning portions.

In some embodiments, a server includes a server chassis, a main board, a processor, and a module component. The module component and the processor are connected to the main board. The server chassis includes a cover body and a bottom shell. The cover body is fixed or detachably fixed to the bottom shell to form a vent between the cover body and the module component. The cover body includes a top plate, a slider, and a windshield member. The slider is slidably connected to the top plate or slidably disposed on the top plate. The windshield member is located at the vent and is rotatably pivoted to the top plate. In response to that the slider is moved relative to the top plate, the windshield member is driven by the slider to rotate relative to the top plate, to enable the windshield member to cover the vent.

The objectives, technical content, and features of the present disclosure and the efficacy achieved by the present disclosure are easily understood in the following detailed descriptions by using the specific embodiments with reference to the accompanying drawings.

### BRIEF DESCRIPTION OF THE DRAWINGS

FIG. 1A is a schematic front perspective view of a server chassis according to a first embodiment;

FIG. 1B is a schematic front perspective view of a cover body of the server chassis shown in FIG. 1A;

FIG. 2 is a schematic rear perspective view of the cover body shown in FIG. 1;

FIG. 3 is a schematic exploded view of the cover body shown in FIG. 1;

FIG. 4 is a schematic perspective view of a slider, a linkage member, and a windshield member shown in FIG. 1;

FIG. 5 is a schematic top view of the cover body shown in FIG. 1, where a detent member is located at a first fixed position L1, a slider is located at a first position P1, and a windshield member is located at a first angular position A1;

FIG. 6 is a schematic top view of the cover body shown in FIG. 1, where a detent member is located at a second fixed position L2, a slider is located at a second position P2, and a windshield member is located at a second angular position A2;

FIG. 7 is a schematic partially enlarged view of a region 7 of the cover body shown in FIG. 5;

FIG. 8 is a schematic side view of the cover body shown in FIG. 5;

FIG. 9 is a schematic side view of the cover body shown in FIG. 6;

FIG. 10 is a schematic front view of the cover body shown in FIG. 5;

FIG. 11 is a schematic front view of the cover body shown in FIG. 6;

FIG. 12 is a schematic side view of a cover body according to a second embodiment, where a detent member is located at a first fixed position, a slider is located at a first position, and a windshield member is located at a first angular position;

FIG. 13 is a schematic side view of the cover body shown in FIG. 12, where the detent member is located at a second fixed position, the slider is located at a second position, and the windshield member is located at a second angular position;

FIG. 14 is a schematic top view of a cover body according to a third embodiment, where a detent member is located at a first fixed position, a slider is located at a first position, and a windshield member is located at a first angular position;

FIG. 15 is a schematic top view of the cover body shown in FIG. 14, where the detent member is located at a second fixed position, the slider is located at a second position, and the windshield member is located at a second angular position;

FIG. 16 is a schematic top view of a cover body according to a fourth embodiment, where a detent member is located at a first fixed position, a slider is located at a first position, and a windshield member is located at a first angular position;

FIG. 17 is a schematic top view of the cover body shown in FIG. 16, where the detent member is located at a second fixed position, the slider is located at a second position, and the windshield member is located at a second angular position;

FIG. 18 is a schematic partially enlarged view of a region 18 of the cover body shown in FIG. 16;

FIG. 19 is a schematic top view of a cover body according to a fifth embodiment, where a detent member is located at a first fixed position, a slider is located at a first position, and a windshield member is located at a first angular position;

FIG. 20 is a schematic top view of the cover body shown in FIG. 19, where the detent member is located at a second fixed position, the slider is located at a second position, and the windshield member is located at a second angular position;

FIG. 21 is a schematic partially enlarged front perspective diagram of a region 21 of the cover body shown in FIG. 19;

FIG. 22 is a schematic partially enlarged rear perspective view of the cover body shown in FIG. 21;

FIG. 23 is a schematic rear perspective view of a cover body according to a sixth embodiment; and

FIG. 24 is a schematic perspective view of a server according to some embodiments.

### DETAILED DESCRIPTION

The embodiments of the present disclosure will be described in detail below by way of example and with reference to the accompanying drawings. In the description of this specification, many specific details are provided to provide a thorough understanding of the present disclosure. However, the present disclosure may be implemented without some or all of the specific details. The same or similar elements in the accompanying drawings will be denoted by the same or similar symbols. It should be noted that the accompanying drawings are only schematic and do not represent actual sizes or quantities of elements. Some details may not be completely drawn, so as to keep the accompanying drawings concise.

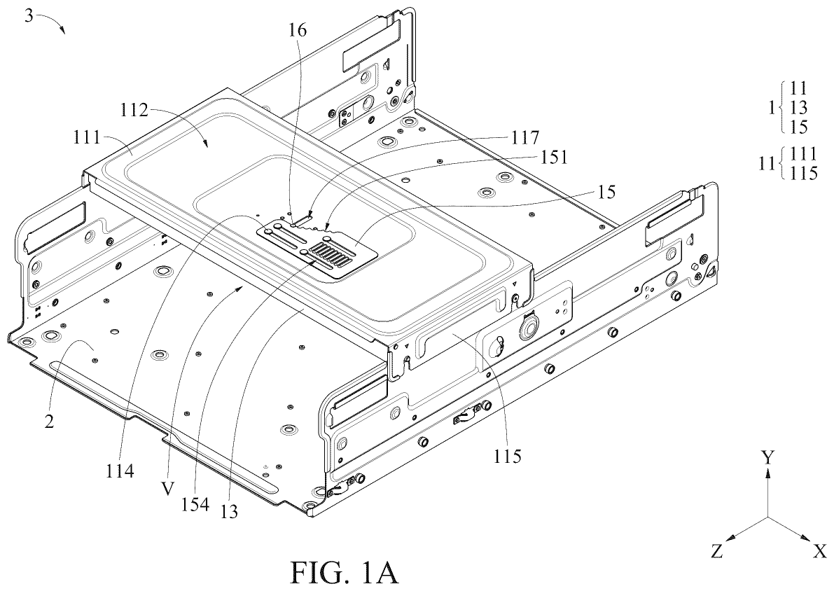

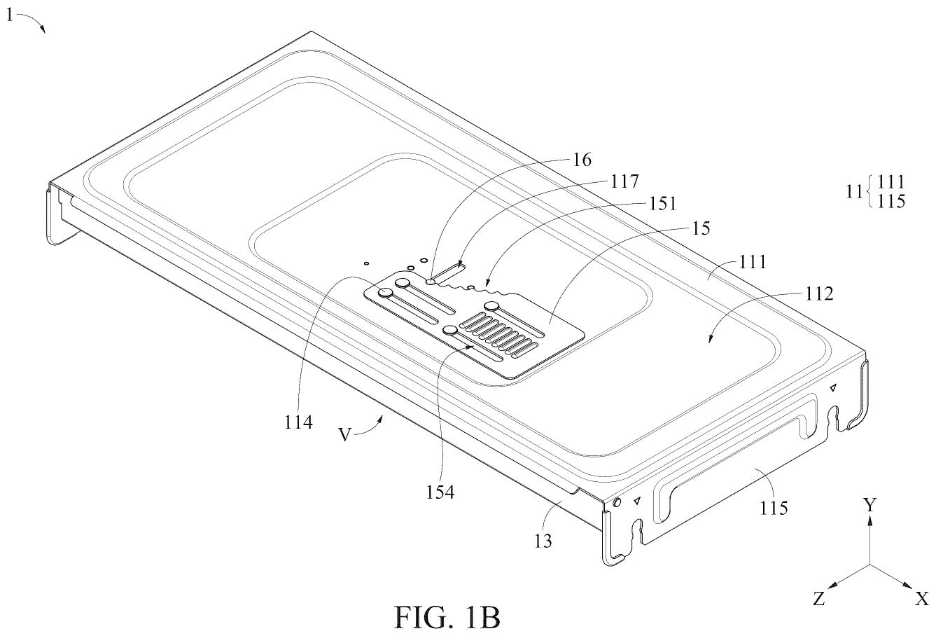

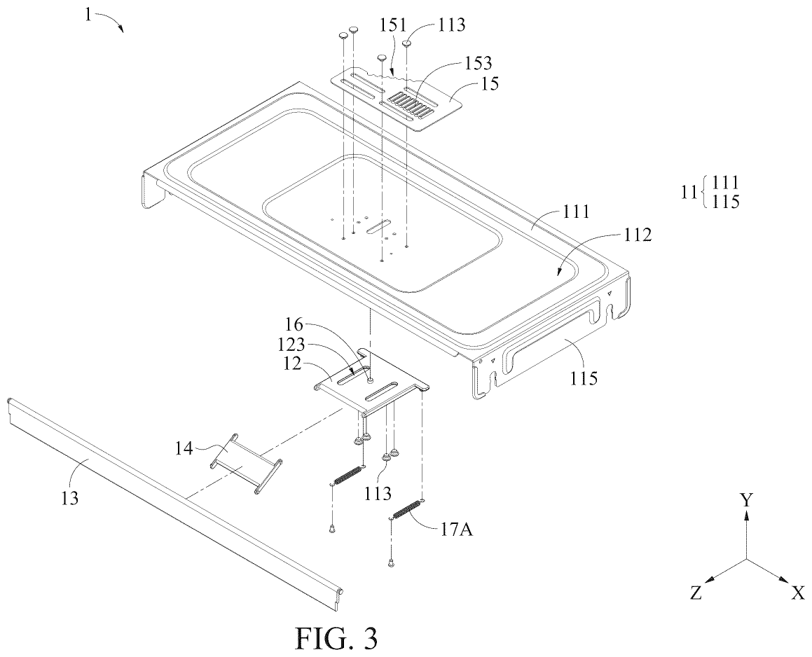

Please refer to FIG. 1A to FIG. 3. FIG. 1A is a schematic front perspective view of a server chassis according to a first embodiment. FIG. 1B is a schematic front perspective view of a cover body of the server chassis shown in FIG. 1A. A server chassis 3 includes a cover body 1. The cover body 1 may be adapted for being assembled to a bottom shell 2. The cover body 1 includes a top plate 11, a slider 12, and a windshield member 13. The slider 12 is slidably connected to the top plate 11 or slidably disposed on the top plate 11. The windshield member 13 is rotatably pivoted to the top plate 11. In response to that the slider 12 is moved relative to the top plate 11, the slider 12 drives the windshield member 13 to rotate relative to the top plate 11. Therefore, in response to that the windshield member 13 stays at different pivot positions, a distance between the windshield member 13 and the bottom shell 2 is different. In this way, the windshield member 13 can pivot in response to a height of a server component configured in the server chassis 3 to adjust a size of a vent V (that is, the windshield member 13 covers at least a part of the vent V, and details are described below). Specifically, in some embodiments, the vent V is formed between the cover body 1 and the bottom shell 2.

In the embodiment of FIG. 1A, the cover body 1 is disposed above the bottom shell 2, but the present disclosure is not limited thereto. The cover body 1 may be disposed at a front side, a rear side, a left side, or a right side of the bottom shell 2 of a server. A structure of the bottom shell 2 may be adjusted in accordance with a position at which the cover body 1 is disposed.

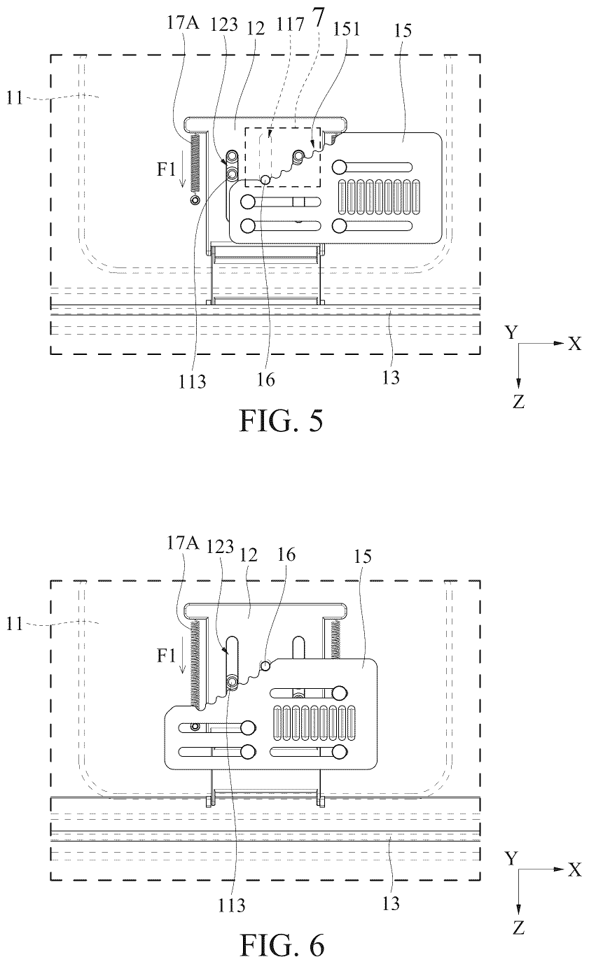

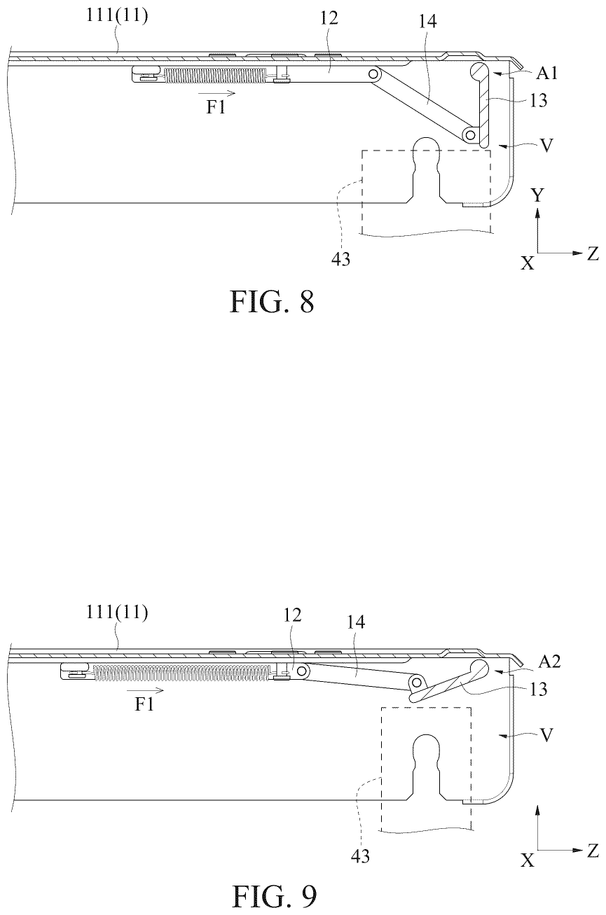

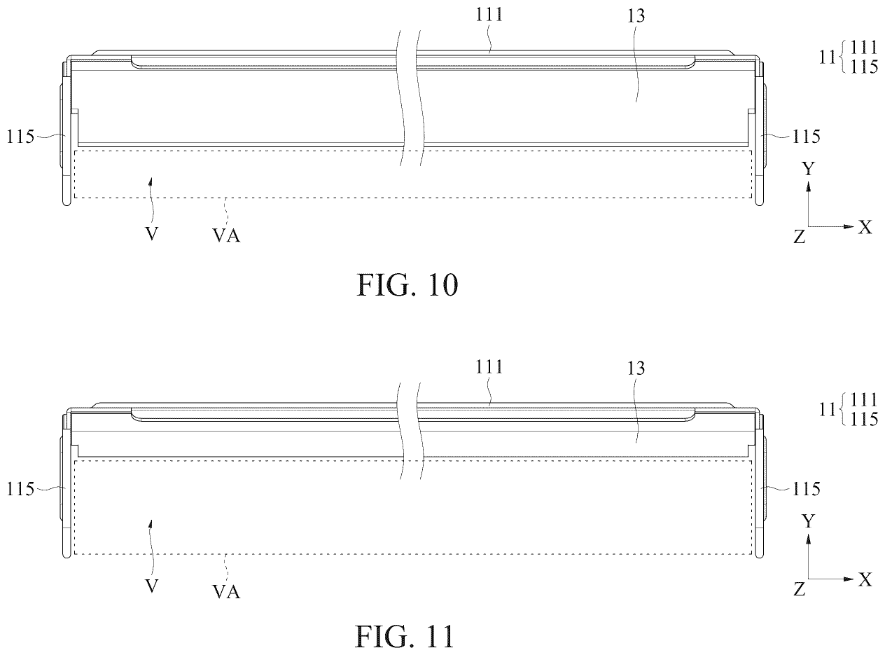

In some embodiments, the slider 12 is slidably connected to the top plate 11 or slidably disposed on the top plate 11 to enable the slider 12 to be at a first position P1 or a second position P2. For the slider 12 located at the first position P1, please refer to FIG. 5, and for the slider 12 located at the second position P2, please refer to FIG. 6. The windshield member 13 is pivoted to the top plate 11 to enable the windshield member 13 to be at a first angular position A1 or a second angular position A2 and form a connection relationship with the slider 12. For the windshield member 13 located at the first angular position A1, please refer to FIG. 8 and FIG. 10, and for the windshield member 13 located at the second angular position A2, please refer to FIG. 9 and FIG. 11. Please refer to FIG. 5, FIG. 6, and FIG. 8 to FIG. 11. In response to that the slider 12 is moved from the first position P1 toward the second position P2, the windshield member 13 causes the windshield member 13 to rotate from the first angular position A1 toward the second angular position A2 under a connection relationship. It can be seen from FIG. 8 to FIG. 11 that, when a case where the windshield member 13 is located at the first angular position A1 (FIG. 8 and FIG. 10) is compared with a case where the windshield member 13 is located at the second angular position A2 (FIG. 9 and FIG. 11), when the windshield member 13 is located at the first angular position A1, the vent V is more covered. A remaining area VA (an area viewed at a viewing angle of FIG. 10, i.e., the area not covered by the windshield member 13) of the vent V in FIG. 10 (where the windshield member 13 is located at the first angular position A1) is smaller than a remaining area VA (an area viewed at a viewing angle of FIG. 11) of the vent V in FIG. 11 (where the windshield member 13 is located at the second angular position A2). Therefore, the cover body 1 can effectively adapt to wind-shielding requirements of servers of different heights by using the slider 12 and the windshield member 13 to provide heat dissipation for servers of different heights.

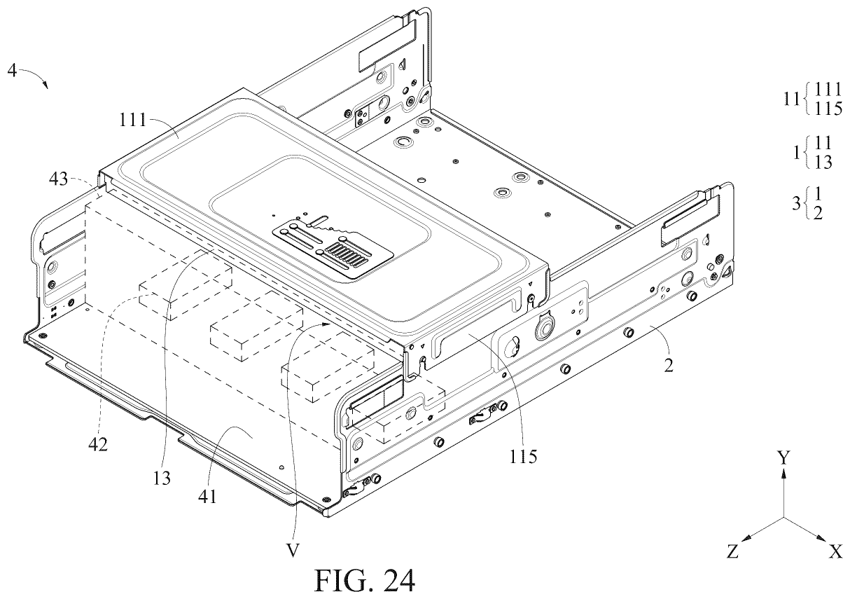

Specifically, please refer to FIG. 8, FIG. 9, and FIG. 24 when reading the following description. A main board 41 is accommodated in the server chassis 3 (FIG. 24 shows that the main board 41 is disposed on the bottom shell 2). The main board 41 includes a module component 43 (described below). The cover body 1 is fixed or detachably fixed to the bottom shell 2 to form a vent V between the cover body 1 and the module component 43. In response to that the slider 12 is moved relative to the top plate 11, the slider 12 drives the windshield member 13 to rotate relative to the top plate 11, to enable the windshield member 13 to cover the vent V. That the windshield member 13 covers the vent V may be that the windshield member 13 essentially covers the vent V, or that after the windshield member 13 covers the vent V, there is still a predetermined gap between the windshield member 13 and the vent V. Please refer to FIG. 8 and FIG. 9. A height of the module component 43 in the embodiment of FIG. 8 is different from a height of the module component 43 in the embodiment of FIG. 9. It can be seen from the figures that a user may adjust the slider 12 to cause the windshield member 13 to rotate to match different heights of module components 43 of different servers to achieve a desired wind-shielding effect.

Please refer to FIG. 1A, FIG. 1B, and FIG. 8 to FIG. 11. In some embodiments, the top plate 11 includes an upper board 111 and two side boards 115. Each of two sides of the upper board 111 is connected to one of the side boards 115 to form the vent V. The windshield member 13 is pivoted to the top plate 11 and is located at the vent V. In other words, two ends of a side of the windshield member 13 adjacent to the top plate 11 are connected to two ends of a side of the top plate 11, and the windshield member 13 can be rotated to the first angular position A1 or the second angular position A2. A coverage area of the windshield member 13 over the vent V differs in response to whether the windshield member 13 is located at the first angular position A1 or the second angular position A2. The remaining area VA of the vent V can be adjusted through whether the windshield member 13 located at the first angular position A1 or the second angular position A2 to correspond to wind-shielding requirements of servers of different heights. In some embodiments, an angle between the windshield member 13 located at the first angular position A1 and the upper board 111 is greater than an angle between the windshield member 13 located at the second angular position A2 and the upper board 111. In some embodiments, the angle between the windshield member 13 located at the first angular position A1 and the upper board 111 is 90 degrees; that is, the windshield member 13 located at the first angular position A1 and the upper board 111 are perpendicular to each other. In some embodiments, the angle between the windshield member 13 located at the second angular position A2 and the upper board 111 is an acute angle. When the windshield member 13 is located at the first angular position A1, the windshield member 13 can provide a larger wind-shielding area, an area of the vent V that is covered by the windshield member 13 is larger; that is, the remaining area VA of the vent V is smaller, and the cover body 1 is adapted for a server with a lower height. However, when the windshield member 13 is located at the second angular position A2, the windshield member 13 can provide a smaller wind-shielding area, an area of the vent V that is covered by the windshield member 13 is smaller; that is, the remaining area VA of the vent V is larger, and the cover body 1 is adapted for a server with a higher height.

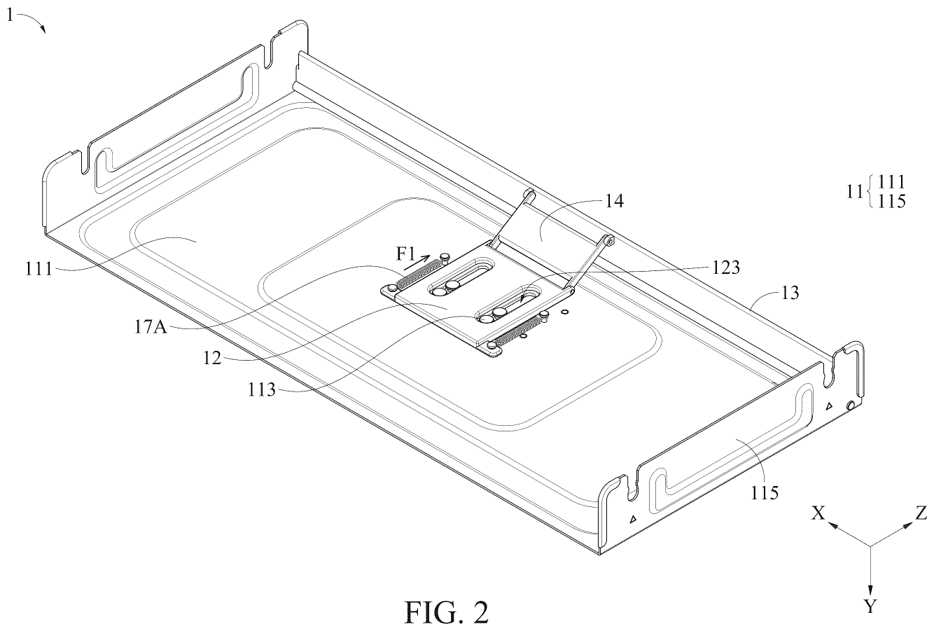

In some embodiments, a sliding relationship between the top plate 11 and the slider 12 is implemented by using a sliding rail and a sliding column which corresponds to each other. Please refer to FIG. 2, FIG. 5, FIG. 6, FIG. 8, and FIG. 9. In some embodiments, a first sliding column 113 is disposed on the top plate 11, the slider 12 has a first sliding rail 123, and the first sliding column 113 is slidably disposed on the first sliding rail 123 to enable the slider 12 to move to the first position P1 or the second position P2 along the first sliding rail 123 by using the first sliding column 113; that is, the first sliding column 113 slides by being guided by the first sliding rail 123. In some embodiments, the first sliding column 113 is a rivet penetrating through the top plate 11. In some embodiments, the first sliding column 113 is disposed on the upper board 111 of the top plate 11. In some other embodiments, the first sliding column 113 and the first sliding rail 123 may also be exchanged, the top plate 11 has the first sliding rail 123, the slider 12 is provided with the first sliding column 113, and the first sliding column 113 is slidably disposed on the first sliding rail 123 to enable the slider 12 to be moved to the first position P1 or the second position P2 along the first sliding rail 123 by using the first sliding column 113. In some embodiments, the first sliding column 113 is a rivet penetrating through the slider 12. In some embodiments, the first sliding rail 123 is disposed on the upper board 111 (not shown in the figure) of the top plate 11.

In some embodiments, the slider 12 has at least one first sliding rail 123, the top plate 11 is provided with at least one first sliding column 113, and the first sliding column 113 corresponds to the first sliding rail 123 such that a sliding relationship is formed between the first sliding column 113 and the first sliding rail 123 to enable the first sliding column 113 and the first sliding rail 123 to slide relative to each other. Please refer to FIG. 2, FIG. 5, FIG. 6, FIG. 8, and FIG. 9. In some embodiments, the slider 12 has two first sliding rails 123, the top plate 11 is provided with four first sliding columns 113, and two of the first sliding columns 113 correspond to one first sliding rail 123 to enable the first sliding columns 113 and the first sliding rails 123 to slide relative to each other more stably. In some other embodiments, the slider 12 has three first sliding rails 123, the top plate 11 is provided with six first sliding columns 113, and two first sliding columns 113 correspond to one first sliding rail 123 to enable the first sliding column 113 and the first sliding rail 123 to slide relative to each other more stably (not shown in the figure). In some embodiments, a sliding relationship between the top plate 11 and the slider 12 enables the top plate 11 and the slider 12 to slide relative to each other in parallel. In some embodiments, the slider 12 slides in parallel along a surface of the top plate 11.

Please refer to FIG. 1A to FIG. 3. In a first embodiment, a connection relationship between the windshield member 13 and the slider 12 is implemented through a linkage member 14. In some embodiments, the cover body 1 further includes the linkage member 14 to enable the windshield member 13 to form a connection relationship with the slider 12. Two ends of the linkage member 14 are respectively pivoted to the slider 12 and the windshield member 13 such that, in response to that the slider 12 is moved relative to the top plate 11, the slider 12 causes the windshield member 13 to rotate relative to the top plate 11. For example, in some embodiments, that the slider 12 causes the windshield member 13 to rotate is achieved through the linkage member 14. In the embodiment of the drawings, in response to that the slider 12 is moved from the first position P1 toward the second position P2, the slider 12 causes the windshield member 13 to rotate from the first angular position A1 toward the second angular position A2. Please refer to FIG. 8 and FIG. 9. In some embodiments, in response to that the windshield member 13 is located at the first angular position A1, an angle between the windshield member 13 and the linkage member 14 is an acute angle, and in response to that the windshield member 13 is located at the second angular position A2, an angle between the windshield member 13 and the linkage member 14 is an obtuse angle.

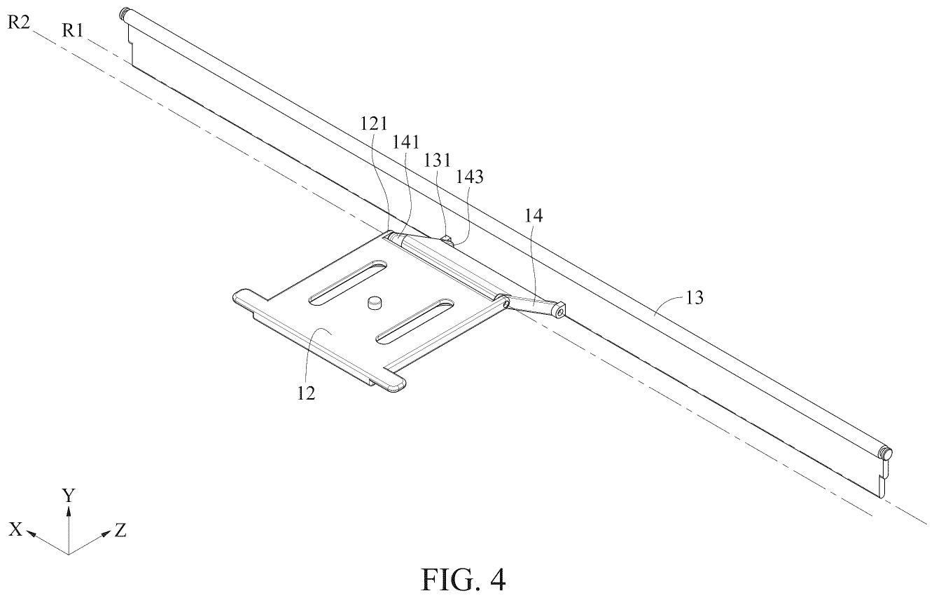

In some embodiments, the linkage member 14 is any element that can achieve connection between the windshield member 13 and the slider 12. For example, the linkage member 14 may be a rod-like element or a board-like element. Please refer to FIG. 4. In some embodiments, the linkage member 14 is a plate member. Two protruding arms provided on one of the two sides of the plate member are two first pivot arms 141, and two protruding arms provided on the other of the two sides of the plate member are two second pivot arms 143. The two first pivot arms 141 are pivoted to the slider 12, and the two second pivot arms 143 are pivoted to the windshield member 13. In some embodiments, the slider 12 includes two third pivot arms 121 pivoted to the two first pivot arms 141 of the linkage member 14, and the windshield member 13 includes two fourth pivot arms 131 pivoted to the two second pivot arms 143 of the linkage member 14. Corresponding pivot arms have corresponding pairs of holes and protruding columns to achieve pivotal connection. In some embodiments, the first pivot arm 141 has a protruding column to achieve pivotal connection with a hole of the third pivot arm 121, and the second pivot arm 143 has a protruding column to achieve pivotal connection with a hole of the fourth pivot arm 131, but the present disclosure is not limited thereto. In some other embodiments, the third pivot arm 121 has a protruding column to achieve pivotal connection with a hole of the first pivot arm 141, and the fourth pivot arm 131 has a protruding column to achieve pivotal connection with a hole of the second pivot arm 143. In some embodiments, the first pivot arm 141, the second pivot arm 143, the third pivot arm 121, and the fourth pivot arm 131 are elastic.

Please refer to FIG. 4. In some embodiments, a pivotal axis (a first pivotal axis R1) between the windshield member 13 and the top plate 11 is different from a pivotal axis (a second pivotal axis R2) between the windshield member 13 and the linkage member 14. In other words, the first pivotal axis R1 and the second pivotal axis R2 are non-coaxially disposed. In some embodiments, the first pivotal axis R1 and the second pivotal axis R2 are at a specific distance from each other and are not located in a same horizontal plane. In some embodiments, the first pivotal axis R1 and the second pivotal axis R2 are located at two opposite sides of the windshield member 13.

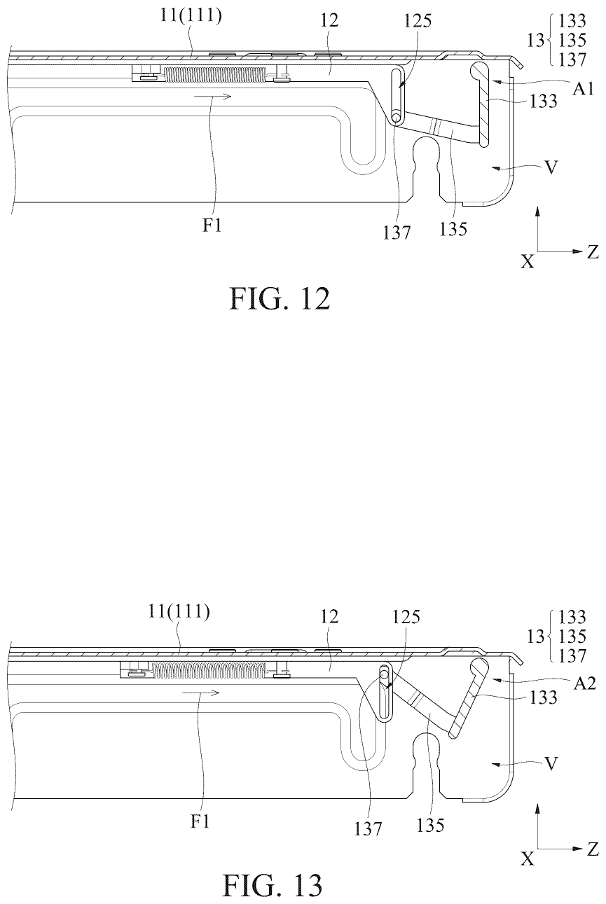

Please refer to FIG. 12 and FIG. 13. In a second embodiment, a connection relationship between the windshield member 13 and the slider 12 is achieved through a pivotal-sliding relationship between the windshield member 13 and the slider 12. In some embodiments, the windshield member 13 includes a shielding plate 133 and a connecting arm 135. One end of the shielding plate 133 is pivoted to the top plate 11, the other end of the shielding plate 133 is fixed to one of two ends of the connecting arm 135, and the other end of the connecting arm 135 that is not fixed to the shielding plate 133 is pivotally and slidably disposed on the slider 12 such that, in response to that the slider 12 is moved from the first position P1 toward the second position P2, the windshield member 13 is rotated and slides on the slider 12 through the connecting arm 135 so that the windshield member 13 is rotated from the first angular position A1 toward the second angular position A2. The foregoing “pivotally and slidably disposed” means that the other end of the connecting arm 135 can not only slide relative to (a pivotal-sliding position of) the slider 12 but also pivot relative to (a pivotal-sliding position of) the slider 12.

Please refer to FIG. 12 and FIG. 13. In some embodiments, the other end of the connecting arm 135 has a second sliding column 137, the slider 12 has a second sliding rail 125, and the second sliding column 137 is pivotally and slidably disposed on the second sliding rail 125 to enable the windshield member 13 to slide along the second sliding rail 125 by using the second sliding column 137 and to be rotated to the first angular position A1 or the second angular position A2. The foregoing “pivotal-sliding position” refers to the second sliding rail 125. In some embodiments, the second sliding rail 125 is disposed at two ends of a side of the slider 12. In some embodiments, since the shielding plate 133 is fixed to the connecting arm 135, regardless of whether the windshield member 13 is located at the first angular position A1 or the second angular position A2, the angle between the windshield member 13 and the linkage member 14 is fixed. In some embodiments, the angle between the windshield member 13 and the linkage member 14 is an acute angle or a right angle. Please refer to FIG. 12 and FIG. 13. In some embodiments, the angle between the windshield member 13 and the linkage member 14 is an acute angle.

In some embodiments, different positioning manners are implemented on the cover body 1 to position the slider 12 located at the first position P1 or the second position P2, and to further position the windshield member 13 located at the first angular position A1 or the second angular position A2. Therefore, the windshield member 13 can stably adapt to wind-shielding requirements of servers of different heights and provide thermal requirements of servers of different heights.

Please refer to FIG. 1A, FIG. 1B, FIG. 5, and FIG. 6. In the first embodiment, the cover body 1 is positioned by using the detent member 15 and the positioning member 16. In some embodiments, the cover body 1 further includes a detent member 15 and a positioning member 16, the detent member 15 has a plurality of positioning portions 151, the positioning member 16 is fixed to the slider 12, and the positioning member 16 is selectively located at one of the plurality of positioning portions 151.

In some embodiments, the top plate 11 has a sliding groove 117, and the positioning member 16 is slidably disposed in the sliding groove 117 and is selectively located at one of the plurality of positioning portions 151. The positioning member 16 is selectively maintained at one of the plurality of positioning portions 151 to correspondingly maintain a pivot position of the windshield member 13. In some embodiments, the sliding groove 117 is disposed on the upper board 111 of the top plate 11. In some embodiments, the sliding groove 117 and the first sliding rail 123 are disposed in parallel.

In some embodiments, the detent member 15 is slidably disposed on the top plate 11 to enable the detent member 15 to be at the first fixed position L1 or the second fixed position L2, to enable the slider 12 to be correspondingly located at the first position P1 or the second position P2, and to further enable the windshield member 13 to be correspondingly located at the first angular position A1 or the second angular position A2. Please refer to FIG. 5 for the detent member 15 located at the first fixed position L1, and please refer to FIG. 6 for the detent member 15 located at the second fixed position L2. In response to that the detent member 15 is moved from the first fixed position L1 toward the second fixed position L2, the positioning member 16 moves from one of the plurality of positioning portions 151 toward another of the plurality of positioning portions 151 to drive the slider 12 to move from the first position P1 toward the second position P2. Thereby, the windshield member 13 can be rotated from the first angular position A1 toward the second angular position A2 through the connection relationship between the slider and the windshield member.

In some embodiments, a sliding relationship between the detent member 15 and the top plate 11 is implemented by using a sliding rail and a sliding column which correspond to each other. Please refer to FIG. 1A and FIG. 1B. In some embodiments, a third sliding column 114 is disposed on the top plate 11, the detent member 15 has a third sliding rail 154, and the third sliding column 114 is slidably disposed on the third sliding rail 154 to enable the detent member 15 to be moved to the first fixed position L1 or the second fixed position L2 along the third sliding rail 154 by using the third sliding column 114; that is, the third sliding column 114 slides by being guided by the third sliding rail 154. In some embodiments, the third sliding column 114 is a rivet penetrating through the top plate 11. In some embodiments, the third sliding column 114 is disposed on the upper board 111 of the top plate 11. In some other embodiments, the third sliding column 114 and the third sliding rail 154 may also be exchanged, the top plate 11 has the third sliding rail 154, the detent member 15 is provided with the third sliding column 114, and the third sliding column 114 is slidably disposed on the third sliding rail 154 to enable the detent member 15 to move to the first fixed position L1 or the second fixed position L2 along the third sliding rail 154 by using the third sliding column 114. In some embodiments, the third sliding column 114 is a rivet penetrating through the detent member 15. In some embodiments, the third sliding rail 154 is disposed on the upper board 111 of the top plate 11 (not shown in the figure).

In some embodiments, the detent member 15 has at least one third sliding rail 154, the top plate 11 is provided with at least one third sliding column 114, and the third sliding column 114 corresponds to the third sliding rail 154 such that a sliding relationship is formed between the third sliding column 114 and the third sliding rail 154 to enable the third sliding column 114 and the third sliding rail 154 to slide relative to each other. In some embodiments, the detent member 15 has three third sliding rails 154, the top plate 11 is provided with three third sliding columns 114, and the third sliding column 114 corresponds to the third sliding rail 154 to enable the third sliding columns 114 and the third sliding rails 154 to slide relative to each other more stably. Please refer to FIG. 1A and FIG. 1B. In some embodiments, the detent member 15 has four third sliding rails 154, the top plate 11 is provided with four third sliding columns 114, and the third sliding columns 114 correspond to the third sliding rails 154 to enable the third sliding columns 114 and the third sliding rails 154 to slide relative to each other more stably. In some embodiments, a sliding relationship between the top plate 11 and the detent member 15 enables the top plate 11 and the detent member 15 to slide relative to each other in parallel. In some embodiments, the detent member 15 slides in parallel along the surface of the top plate 11. In some embodiments, the detent member 15 and the slider 12 respectively correspond to opposite surfaces of the top plate 11. In some embodiments, the third sliding rail 154 and the first sliding rail 123 are disposed perpendicularly to each other. In some embodiments, the third sliding rail 154 and the sliding groove 117 are disposed perpendicularly to each other.

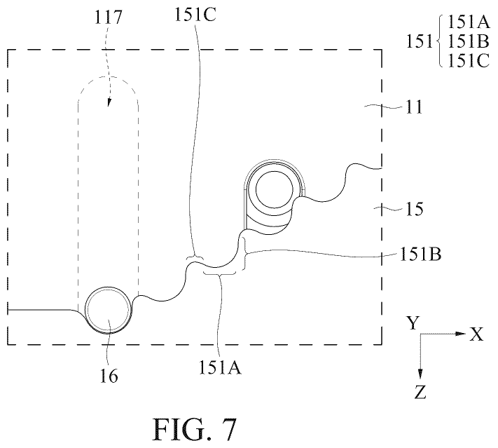

Please refer to FIG. 7. In the first embodiment, each of the positioning portions 151 includes a positioning sub-portion 151A and an abutting sub-portion 151B. One end of the positioning sub-portion 151A is connected to the abutting sub-portion 151B. That the positioning member 16 is located at one of the plurality of positioning portions 151 is that the positioning member 16 is located at the positioning sub-portion 151A of one of the plurality of positioning portions 151. In response to that the detent member 15 is moved from the first fixed position L1 toward the second fixed position L2, the abutting sub-portion 151B abuts against the positioning member 16. In other words, in response to that the detent member 15 is moved to the left side, that is, moves toward the positioning member 16, the abutting sub-portion 151B abuts against the positioning member 16. In some embodiments, each of the positioning portions 151 further includes a guide sub-portion 151C. The guide sub-portion 151C is connected to another end of the positioning sub-portion 151A, and the guide sub-portion 151C is configured to guide the positioning member 16 to leave the positioning sub-portion 151A. In response to that the detent member 15 is moved from the second fixed position L2 toward the first fixed position L1, the positioning member 16 can be guided, by using the guide sub-portion 151C, to move to a next position, that is, another positioning sub-portion 151A. In other words, in response to that the detent member 15 is moved to the right side, that is, moves away from the positioning member 16, the slider 12 is moved by one positioning sub-portion 151A toward the first position P1, and therefore an opening of the windshield member 13 becomes smaller. In some embodiments, angles, such as acute angles, are formed between the movement path of the positioning member 16 and the plurality of positioning portions 151. In some embodiments, angles, such as acute angles, are formed between the sliding groove 117 and the plurality of positioning portions 151.

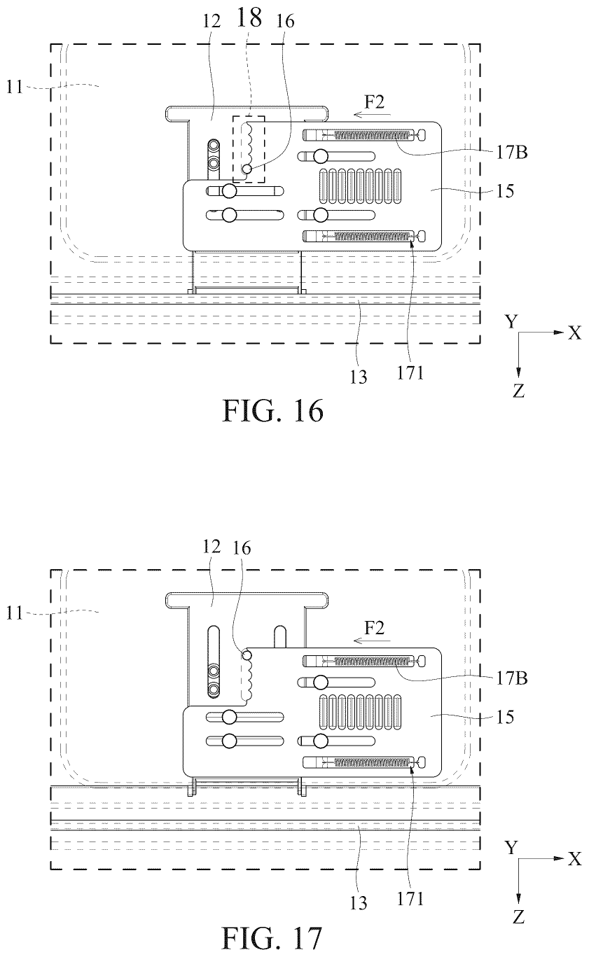

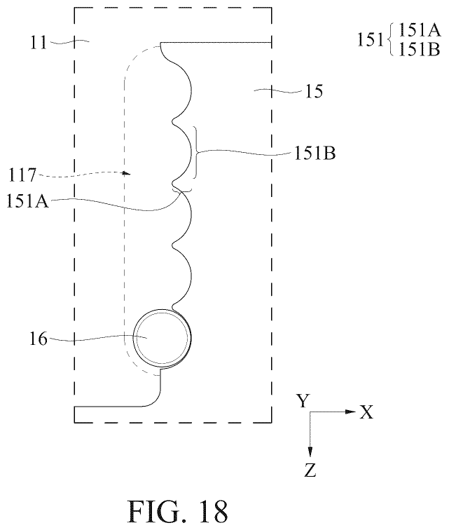

Please refer to FIG. 16 and FIG. 17. In a fourth embodiment, the cover body 1 is also positioned by using the detent member 15 and the positioning member 16. Please refer to FIG. 18. In some embodiments, each of the positioning portions 151 includes a positioning sub-portion 151A and an abutting sub-portion 151B. One end of the positioning sub-portion 151A is connected to the abutting sub-portion 151B, and that the positioning member 16 is located at one of the plurality of positioning portions 151 is that the positioning member 16 is located at the positioning sub-portions 151A of one of the plurality of positioning portions 151. In some embodiments, a movement path of the positioning member 16 is parallel to the plurality of positioning portions 151. In some embodiments, the sliding groove 117 is parallel to the plurality of positioning portions 151.

Please refer to FIG. 1A and FIG. 1B. In some embodiments, the top plate 11 has a groove 112, and the detent member 15 is accommodated in the groove 112. In response to that the detent member 15 is accommodated in the groove 112, the surface of the top plate 11 can be maintained to be planar without any element projecting out of the surface of the top plate 11.

In some embodiments, a surface of the detent member 15 is provided with a pushing portion 153, and a force is applied to the pushing portion 153 to enable the positioning member 16 to be selectively located at one of the plurality of positioning portions 151. In some embodiments, the pushing portion 153 is perpendicular to the sliding groove 117. In some embodiments, the pushing portion 153 is perpendicular to the first sliding rail 123. In some embodiments, the pushing portion 153 is parallel to the third sliding rail 154. In some embodiments, the pushing portion 153 protrudes from the surface of the detent member 15 to provide an anti-slip effect.

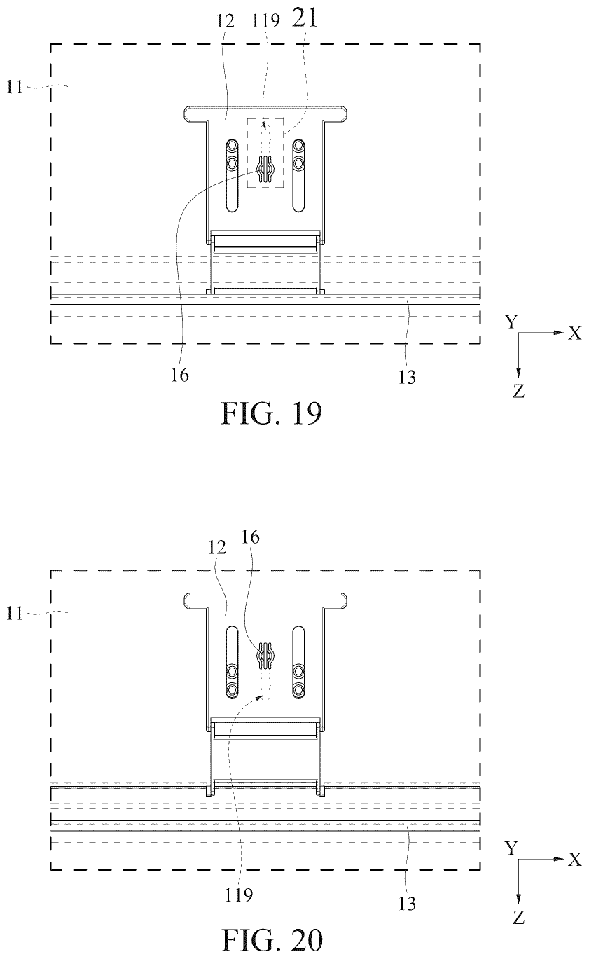

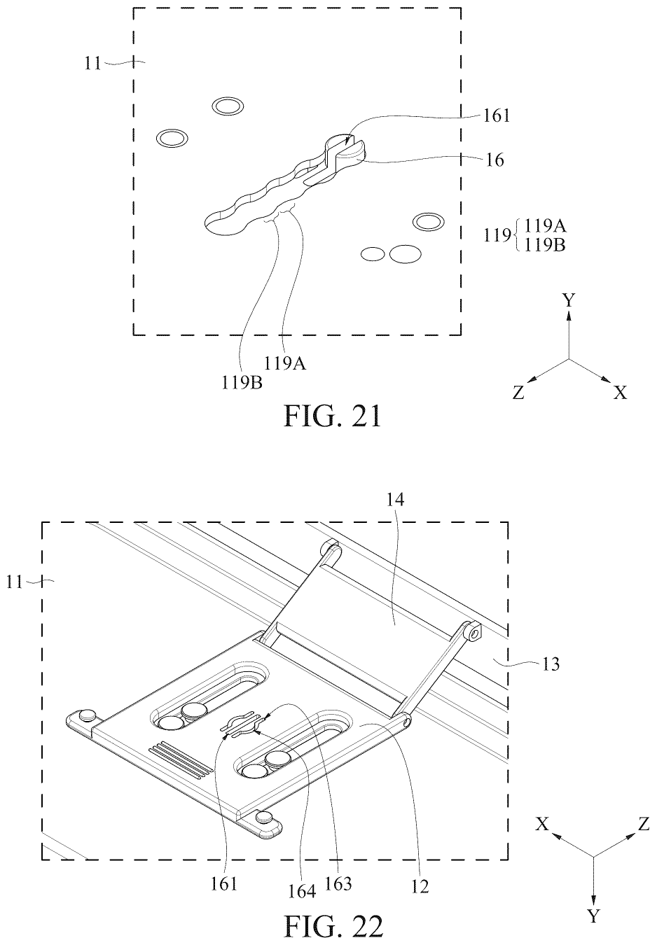

Please refer to FIG. 19 to FIG. 21. In a fifth embodiment, the cover body 1 is positioned by using the positioning member 16 and the positioning sliding groove 119. Please refer to FIG. 21. In some embodiments, the cover body 1 further includes a positioning member 16, the top plate 11 has a positioning sliding groove 119, the positioning sliding groove 119 has a plurality of neck portions 119A which form a plurality of maintaining portions 119B, and the positioning member 16 is selectively located at one of the plurality of maintaining portions 119B. The positioning member 16 is selectively maintained at one of the plurality of maintaining portions 119B to correspondingly maintain the pivot position of the windshield member 13. In some embodiments, the neck portion 119A is located between the plurality of maintaining portions 119B, and a width of the neck portion 119A is smaller than a width of the maintaining portion 119B.

Please refer to FIG. 21 and FIG. 22. In some embodiments, the positioning member 16 has a first channel 161 in the middle to provide the positioning member 16 with a capability to deform and thereby to pass through the plurality of neck portions 119A and to be located at one of the plurality of maintaining portions 119B. In some embodiments, the first channel 161 is in a form of a strip channel, and the first channel 161 is parallel to the positioning sliding groove 119. In some embodiments, the slider 12 on both sides of the positioning member 16, that is, each of portions of the sliders 12 at junctions between the positioning member 16 and the slider 12, has a second channel 163 to provide the positioning member 16 with a capability to further deform and thereby to pass through the plurality of neck portions 119A and to be located at one of the plurality of maintaining portions 119B. In some embodiments, the second channels 163 are in a form of strip channels, and the second channels 163 are parallel to the positioning sliding groove 119. In some embodiments, the second channels 163 are disposed along a junction between the positioning member 16 and the slider 12 to form bent portions 164.

In some embodiments, different maintaining-positioning manners are implemented on the cover body 1 to maintain and position the detent member 15 located at the first fixed position L1 or the second fixed position L2, thereby to maintain and position the slider 12 located at the first position P1 or the second position P2, and to further maintain and position the windshield member 13 located at the first angular position A1 or the second angular position A2. Thereby, the windshield member 13 can stably adapt to wind-shielding requirements of servers of different heights and provide heat dissipation for servers of different heights. In some embodiments, the cover body 1 is maintained and positioned by using any element having elasticity acting on the slider 12 or the detent member 15.

Please refer to FIG. 2, FIG. 5, FIG. 6, FIG. 8, and FIG. 9. In the first embodiment, the cover body 1 is maintained and positioned by using an elastic member 17A. In some embodiments, the cover body 1 further includes the elastic member 17A. Two ends of the elastic member 17A are respectively connected to the slider 12 and the top plate 11. The elastic member 17A applies or constantly applies a first acting force F1 to pull the slider 12 toward the first position P1. In other words, the elastic member 17A provides the first acting force F1 toward the windshield member 13. In some embodiments, a direction in which the elastic member 17A is disposed is parallel to the first sliding rail 123 and/or the sliding groove 117. In some embodiments, a direction in which the elastic member 17A is disposed is perpendicular to the third sliding rail 154. In some embodiments, the elastic member 17A is a tension spring disposed on both sides of the slider 12. In some embodiments, a direction of the first acting force F1 provided by the elastic member 17A is parallel to a direction in which the first sliding rail 123 and/or the sliding groove 117 is disposed. In some embodiments, the direction of the first acting force F1 provided by the elastic member 17A is perpendicular to a direction in which the third sliding rail 154 is disposed.

The following further describes actions between elements used for positioning and elements used for maintaining positioning. Please refer to FIG. 2, FIG. 5, FIG. 6, FIG. 8, and FIG. 9. In some embodiments, in response to that the positioning member 16 is located at the positioning sub-portion 151A, the positioning sub-portion 151A prevents the positioning member 16 and the slider 12 from being pulled toward the first position P1 by the first acting force F1 that is provided by the elastic member 17A and that is toward the first position P1, that is, prevents the positioning member 16 and the slider 12 from being pulled toward a lower part of the drawings by the first acting force F1. In some embodiments, in response to that the detent member 15 is moved toward a direction opposite to the first acting force F1 of the elastic member 17A, the guide sub-portion 151C guides the positioning member 16 to leave the positioning sub-portion 151A.

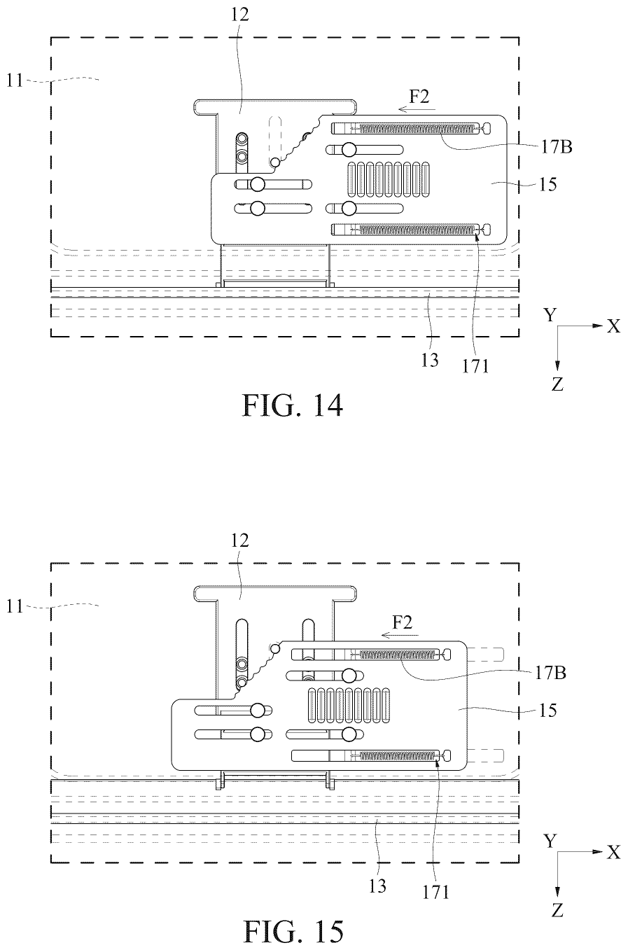

Please refer to FIG. 14 to FIG. 17. In the third and fourth embodiments, the cover body 1 is maintained and positioned by using an elastic member 17B. In some embodiments, the cover body 1 further includes the elastic member 17B. Two ends of the elastic member 17B are respectively connected to the detent member 15 and the top plate 11. The elastic member 17B applies or constantly applies a second acting force F2 to maintain a state in which the positioning member 16 is located at one of the plurality of positioning portions 151 of the detent member 15. In some embodiments, the elastic member 17B provides the second acting force F2 toward the positioning member 16. In some embodiments, the second acting force F2 is a tensile force. In some embodiments, a direction in which the elastic member 17B is disposed is perpendicular to the first sliding rail 123 and/or the sliding groove 117. In some embodiments, the direction in which the elastic member 17B is disposed is parallel to the third sliding rail 154. In some embodiments, the elastic member 17B is a tension spring with one of two ends connected to the top plate 11 and the other end connected to the detent member 15. In some embodiments, a direction of the second acting force F2 provided by the elastic member 17B is perpendicular to the direction in which the first sliding rail 123 and/or the sliding groove 117 is disposed. In some embodiments, a direction of the second acting force F2 provided by the elastic member 17B is perpendicular to a direction in which the third sliding rail 154 is disposed. In some embodiments, the detent member 15 further has an elastic member groove 171 to accommodate the elastic member 17B. Please refer to FIG. 14 to FIG. 17. In this embodiment, the two elastic members 17B are respectively accommodated in the two elastic member grooves 171 to provide the second acting force F2 toward the positioning member 16.

The following further describes actions between elements used for positioning and elements used for maintaining-positioning s. Please refer to FIG. 14 to FIG. 17. In some embodiments, in response to that the detent member 15 is pulled toward the positioning member 16 by the second acting force F2 that is provided by the elastic member 17B and that is toward the positioning member 16, that is, is pulled toward the left side of the drawings, the abutting sub-portion 151B abuts against the positioning member 16.

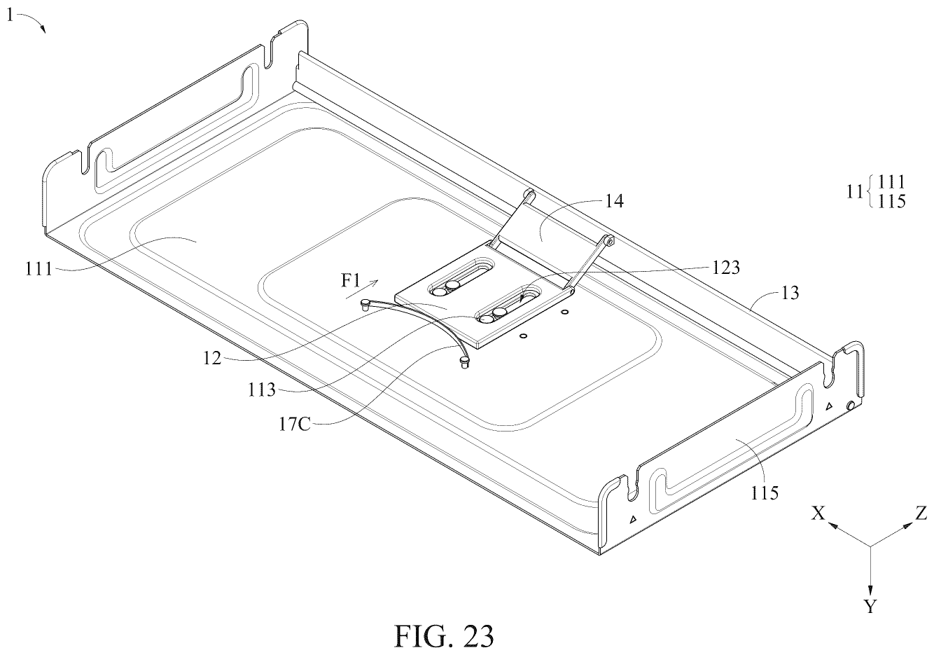

Please refer to FIG. 23. In a sixth embodiment, the cover body 1 is maintained and positioned by using an elastic member 17C. In some embodiments, the cover body 1 further includes the elastic member 17C. One of two ends of the elastic member 17C is connected to the top plate 11, the other end of the elastic member 17C abuts against the slider 12. The elastic member 17C applies or constantly applies a first acting force F1 to push the slider 12 toward a first position P1. In other words, the elastic member 17C provides the first acting force F1 toward the windshield member 13. In some embodiments, a direction in which the elastic member 17C is disposed is parallel to the first sliding rail 123 and/or the sliding groove 117. In some embodiments, the direction in which the elastic member 17C is disposed is perpendicular to the third sliding rail 154. In some embodiments, the elastic member 17C is a spring plate with one of two ends connected to the top plate 11 and the other end abutting against a side of the slider 12 that is opposite to a side adjacent to the linkage member 14. In some embodiments, the elastic member 17B is a stainless steel spring plate. In some embodiments, a direction of the first acting force F1 provided by the elastic member 17C is parallel to the direction in which the first sliding rail 123 and/or the sliding groove 117 is disposed. In some embodiments, the direction of the first acting force F1 provided by the elastic member 17C is perpendicular to a direction in which the third sliding rail 154 is disposed.

Herein, in response to that the positioning member 16 is selectively located at one of the plurality of positioning portions 151, the elastic member 17A, the elastic member 17B, or the elastic member 17C provides the first acting force F1 or the second acting force F2 to enable the positioning member 16 to be maintained at one of the plurality of positioning portions 151 more stably.

Please refer to FIG. 24. FIG. 24 is a schematic perspective view of a server according to some embodiments. In some embodiments, the server 4 includes a server chassis 3, a main board 41, a processor 42, and a module component 43. The module component 43 and the processor 42 are connected to the main board 41. The server chassis 3 includes a cover body 1 and a bottom shell 2. The cover body 1 is fixed or detachably fixed to the bottom shell 2 to form a vent V between the cover body 1 and the module component 43. The cover body 1 includes a top plate 11, a slider 12, and a windshield member 13. The slider 12 is slidably connected to the top plate 11 or slidably disposed on the top plate 11. The windshield member 13 is located at the vent V and is rotatably pivoted to the top plate 11. In response to that the slider 12 is moved relative to the top plate 11, the slider 12 drives the windshield member 13 to rotate relative to the top plate 11. In this way, the windshield member 13 is enabled to cover the vent V. Other implementations of the cover body 1 are described above, and details are not described herein again.

The foregoing module component 43 may be a specific component included in the main board 41. The specific component may be, but is not limited to, a fan, a heat sink, or an accelerator module, where the accelerator module may be, but is not limited to, an OCP accelerator module (OAM for short). The main board 41 may include other components such as a memory. The processor 42, the module component 43, and the memory are electrically connected by using a physical wiring or a trace on a main body (such as a circuit board) of the main board.

In conclusion, some embodiments of the present disclosure provide a server chassis and a server, which can effectively adapt to wind-shielding requirements of servers of different heights and provide heat dissipation for servers of different heights. Thereby, problems in the related art can be improved. In some embodiments, the cover body has a design of a folding linkage mechanism, and an operator can adjust a wind-shielding height of the cover body without another tool. In this way, the cover body has very high operation simplicity. In some embodiments, the operator can adjust the wind-shielding height of the cover body through the surface of the cover body. Thereby, use efficiency and convenience can be improved.

What is claimed is:

1. A server chassis, comprising:
a cover body, including:
a top plate;
a slider, slidably connected to the top plate; and
a windshield member, rotatably pivoted to the top plate, wherein
in response to that the slider is moved relative to the top plate, the windshield member is driven by the slider and is rotated relative to the top plate, and
a bottom shell, wherein the cover body is detachably fixed to the bottom shell.

2. The server chassis according to claim 1, wherein a vent is formed between the cover body and the bottom shell, at least a part of the vent is covered by the windshield member, the slider is slidably connected to the top plate to enable the slider to has a first position or a second position, the windshield member is rotatably pivoted to the top plate to enable the windshield member to has a first angular position and a second angular position, and in response to that the slider is moved from the first position toward the second position, the windshield member is driven by the slider to rotate from the first angular position toward the second angular position.

3. The server chassis according to claim 1, further comprising a linkage member, wherein each of two ends of the linkage member is respectively pivoted to the slider and the windshield member, and in response to that the slider is moved relative to the top plate, the windshield member is caused by the slider to rotate relative to the top plate.

4. The server chassis according to claim 3, wherein the linkage member is a plate member, two protruding arms provided on one of the two sides of the plate member are two first pivot arms, two protruding arms provided on the other of the two sides of the plate member are two second pivot arms, the two first pivot arms are pivoted to the slider, and the two second pivot arms are pivoted to the windshield member.

5. The server chassis according to claim 1, wherein a first sliding column is disposed on the top plate, the slider has a first sliding rail, and the slider is enabled to move to a first position or a second position by the first sliding column being slidably disposed on the first sliding rail in response to that the first sliding column is moved along the first sliding rail.

6. The server chassis according to claim 1, wherein a first sliding column is disposed on the slider, the top plate has a first sliding rail, and the first sliding column is slidably disposed on the first sliding rail to enable the slider to move to a first position or a second position in response to that the first sliding column is moved along the first sliding rail.

7. The server chassis according to claim 1, further comprising a detent member and a positioning member, wherein the detent member has a plurality of positioning portions, the positioning member is fixed to the slider, and the positioning member is selectively located at one of the plurality of positioning portions.

8. The server chassis according to claim 7, wherein the detent member is slidably disposed on the top plate to enable the detent member at a first fixed position or a second fixed position, and in response to that the detent member is moved from the first fixed position toward the second fixed position, the slider is driven to move from a first position toward a second position by the positioning member being moved from one of the plurality of positioning portions toward another one of the plurality of positioning portions, and the windshield member is caused to rotate from a first angular position toward a second angular position.

9. The server chassis according to claim 7, wherein the top plate has a sliding groove, and the positioning member is slidably disposed in the sliding groove and is selectively located at one of the plurality of positioning portions.

10. The server chassis according to claim 7, wherein each of the positioning portions includes a positioning sub-portion and an abutting sub-portion, wherein one end of the positioning sub-portion is connected to the abutting sub-portion, and that the positioning member is located at the positioning sub-portion of one of the plurality of positioning portions.

11. The server chassis according to claim 10, wherein each of the plurality of positioning portions further includes a guide sub-portion, the guide sub-portion is connected to another end of the positioning sub-portion, and the positioning member is guided to leave the positioning sub-portion by the guide sub-portion.

12. The server chassis according to claim 7, further comprising an elastic member, wherein each of two ends of the elastic member is respectively connected to the slider and the top plate, and the elastic member applies a first acting force, and the slider is pulled toward a first position by the first acting force.

13. The server chassis according to claim 7, further comprising an elastic member, wherein each of two ends of the elastic member is respectively connected to the detent member and the top plate, and the elastic member applies a second acting force, and a state in which the positioning member is located at one of the plurality of positioning portions of the detent member is maintained by the second acting force.

14. The server chassis according to claim 7, further comprising an elastic member, wherein one of two ends of the elastic member is connected to the top plate, the other end of the elastic member pushes against the slider, and the elastic member applies a first acting force, and the slider is pushed toward a first position by the first acting force.

15. The server chassis according to claim 7, wherein the top plate has a groove, and the detent member is accommodated in the groove.

16. The server chassis according to claim 7, wherein a surface of the detent member is provided with a pushing portion, and a force is applied to the pushing portion to enable the positioning member to selectively locate at one of the plurality of positioning portions.

17. The server chassis according to claim 1, further comprising a positioning member, wherein the top plate has a positioning sliding groove, the positioning sliding groove has a plurality of neck portions which form a plurality of maintaining portions, and the positioning member is selectively located at one of the plurality of maintaining portions.

18. The server chassis according to claim 1, wherein the windshield member includes a shielding plate and a connecting arm, one of two ends of the connecting arm is fixed to the shielding plate, and the other end of the connecting arm is pivotally and slidably disposed on the slider, and in response to that the slider is moved from a first position toward a second position, the windshield member is caused to rotate from a first angular position toward a second angular position by the windshield member being rotated and sliding on the slider via the connecting arm.

19. A server, comprising:
a main board;
a processor connected to the main board;
a module component, connected to the main board; and
a chassis, including:
a bottom shell, wherein the main board is detachably disposed on the bottom shell; and
a cover body, fixed to the bottom shell, the cover body comprising:
a top plate;
a slider, slidably connected to the top plate; and
a windshield member, rotatably pivoted to the top plate, wherein
in response to that the slider is moved relative to the top plate, the windshield member is driven by the slider and is rotated relative to the top plate.

20. The server according to claim 19, further comprising a linkage member, wherein each of two ends of the linkage member is respectively pivoted to the slider and the windshield member, and in response to that the slider is moved relative to the top plate, the windshield member is caused by the slider to rotate.
